(19) United States
(12) Patent Application Publication
(10) Pub. No.: US 2026/0231483 A1
(43) Pub. Date: Aug. 6, 2026

(54) SEMICONDUCTOR DEVICE

(71) Applicant: Mitsubishi Electric Corporation, Tokyo (JP)

(72) Inventors: Yuri KUNISHIGE, Tokyo (JP); Yasuo ATA, Tokyo (JP)

(73) Assignee: Mitsubishi Electric Corporation, Tokyo (JP)

(21) Appl. No.: 19/420,705

(22) Filed: Dec. 15, 2025

(30) Foreign Application Priority Data
Feb. 5, 2025 (JP) 2025-017517

(51) Int. Cl. H10D 62/10; H10D 62/60; H10D 62/832

(52) U.S. Cl. CPC H10D 62/107; H10D 62/60; H10D 62/8325

(57) ABSTRACT

A semiconductor device includes a semiconductor substrate and a mold resin covering an upper surface and an end surface of the semiconductor substrate. The semiconductor substrate has an effective region, a breakdown voltage holding region outside the effective region, and an outer peripheral region outside the breakdown voltage holding region, the effective region being a region in which a main current flows, the breakdown voltage holding region being a region in which a p-type breakdown voltage holding structure is disposed. An n⁺ impurity layer is disposed in at least a portion of a surface layer in the outer peripheral region. A p⁺ impurity layer is disposed in at least a portion of a surface layer of the n⁺ impurity layer.

### BACKGROUND

### Technical Field

The present disclosure relates to semiconductor devices and relates, in particular, to a semiconductor device having a structure sealed with a mold resin.

### Description of the Background Art

For example, at an outer periphery of a power control semiconductor chip, a high concentration n-type impurity layer serving as a channel stopper that limits spreading of a depletion layer within the semiconductor chip is disposed (e.g., Japanese Patent Application Laid-Open No. 2004-335739).

In a temperature humidity bias (THB) test as a reliability test, breakage (e.g., cracking) of a semiconductor device can occur due to expansion/contraction stress. This breakage is likely to occur at an interface between a semiconductor substrate and a mold region at an end of the semiconductor chip at which the expansion/contraction stress concentrates. Such cracking occurring between different layers is referred to as “interlayer cracking”.

In the semiconductor device including the semiconductor chip including the high concentration n-type impurity layer at the outer periphery thereof, a surface at an end of the semiconductor substrate is in an electron rich state, so that, when interlayer cracking occurs at the end of the semiconductor substrate in the THB test, a discharge current is likely to flow through foreign matter probabilistically present on the surface of the semiconductor substrate. The flow of the discharge current promotes generation of an oxide on the surface of the semiconductor substrate to cause interlayer cracking to further progress.

### SUMMARY

It is an object of the present disclosure to suppress, in a semiconductor device including a semiconductor substrate including a high concentration n-type impurity layer at an outer periphery thereof, a discharge current when interlayer cracking occurs at an end of the semiconductor substrate.

In a semiconductor device according to the present disclosure, a semiconductor substrate has an effective region, a breakdown voltage holding region outside the effective region, and an outer peripheral region outside the breakdown voltage holding region, the effective region is a region in which a main current flows, and the breakdown voltage holding region is a region in which a p-type breakdown voltage holding structure is disposed. An n-type impurity layer is disposed in at least a portion of a surface layer in the outer peripheral region. A p-type impurity layer is disposed in at least a portion of a surface layer of the n-type impurity layer. An upper surface and an end surface of the semiconductor substrate are covered with a mold resin.

According to the present disclosure, a discharge current when interlayer cracking occurs at an end of the semiconductor substrate can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a semiconductor device according to Embodiment 1;

FIG. 2 is a diagram illustrating a modification of the semiconductor device according to Embodiment 1;

FIG. 3 is a diagram illustrating a planar configuration of the semiconductor device according to Embodiment 1;

FIG. 4 is a diagram illustrating a modification of the semiconductor device according to Embodiment 1;

FIG. 5 is a diagram illustrating a modification of the semiconductor device according to Embodiment 1;

FIG. 6 is a diagram illustrating a configuration of a semiconductor device according to Embodiment 2; and

FIG. 7 is a diagram illustrating a configuration of a semiconductor device according to Embodiment 3.

### DESCRIPTION OF THE PREFERRED EMBODIMENTS

In embodiments described below, “n” and “p” represent conductivity types of a semiconductor. An n type with a relatively high impurity concentration is also referred to as “n⁺”, an n type with a relatively low impurity concentration is also referred to as “n⁻”, a p type with a relatively high impurity concentration is also referred to as “p⁺”, and a p type with a relatively low impurity concentration is also referred to as “p⁻”. Assume that a magnitude of an impurity concentration in each region is defined by a peak impurity concentration. That is to say, a region in which the impurity concentration is high (or low) means a region in which a peak impurity concentration is high (or low).

### Embodiment 1

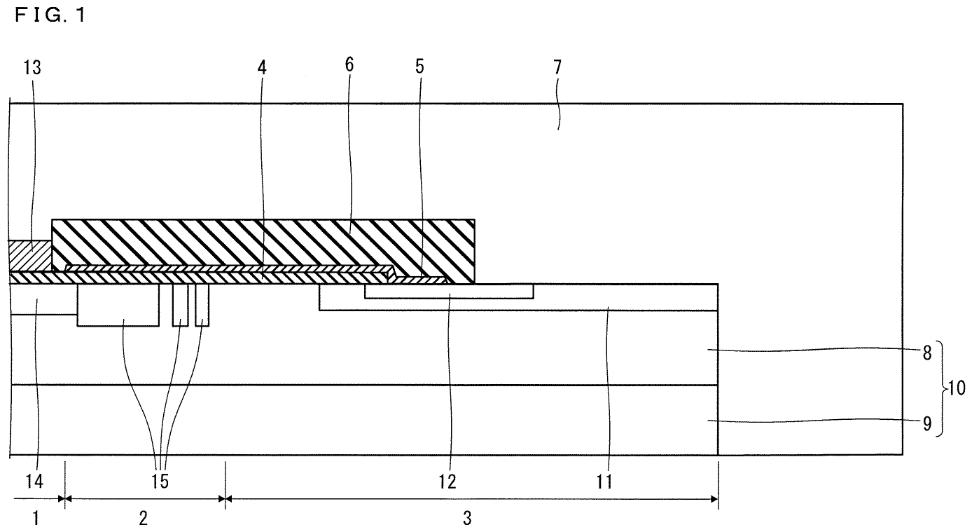

FIG. 1 is a diagram illustrating a configuration of a semiconductor device according to Embodiment 1. As illustrated in FIG. 1, the semiconductor device includes a semiconductor chip including a semiconductor substrate 10. The semiconductor substrate 10 includes an SiC substrate 9 and an SiC epitaxial layer 8 disposed over the SiC substrate 9. While an example in which the semiconductor substrate 10 is made of silicon carbide (SiC) is shown herein, the semiconductor substrate 10 may be made of silicon (Si), for example.

The semiconductor substrate 10 has an effective region 1 in which a main current flows, a breakdown voltage holding region 2 outside the effective region 1, and an outer peripheral region 3 further outside the breakdown voltage holding region 2.

In the effective region 1, a semiconductor element, such as a metal oxide semiconductor field effect transistor (MOSFET), an insulated gate bipolar transistor (IGBT), a Schottky barrier diode (SBD), and a PN junction diode, is disposed. In the present embodiment, the semiconductor element disposed in the semiconductor substrate 10 is assumed to be the MOSFET, and ends of a source electrode 13 and a base layer 14 of the MOSFET are illustrated in FIG. 1. When the semiconductor element disposed in the effective region 1 is the MOSFET, the SiC epitaxial layer 8 is an n-type drift layer, and the SiC substrate 9 is an n-type drain layer. When the semiconductor element disposed in the effective region 1 is the IGBT, the SiC epitaxial layer 8 is an n-type drift layer, and the SiC substrate 9 is a p-type collector layer.

In the breakdown voltage holding region 2 of the semiconductor substrate 10, a p-type breakdown voltage holding structure 15 (e.g., a guard ring) is disposed.

The outer peripheral region 3 is a region at an outermost periphery of the semiconductor substrate 10, that is, at an end of the semiconductor chip. In the outer peripheral region 3, an n⁺ impurity layer 11 as a high concentration n-type impurity region serving as a channel stopper is disposed in at least a portion of a surface layer of the semiconductor substrate 10. A p⁺ impurity layer 12 as a high concentration p-type impurity layer is disposed in at least a portion of a surface layer of the n⁺ impurity layer 11. While the n⁺ impurity layer 11 reaches an end of the semiconductor substrate 10 (the end of the semiconductor chip) in FIG. 1, the n⁺ impurity layer 11 may not reach the end of the semiconductor substrate 10.

A field oxide film 4 is disposed over an upper surface of the semiconductor substrate 10 from an outer periphery of the effective region 1 to an inner periphery of the outer peripheral region 3. A nitride film 5 is disposed over the field oxide film 4. Furthermore, a protective film 6 made of a polyimide resin is disposed over the field oxide film 4 and the nitride film 5. The nitride film 5 covers an outer end of the field oxide film 4, and the protective film 6 covers an outer end of the nitride film 5. Thus, not only the field oxide film 4 but also the nitride film 5 and the protective film 6 have portions being in contact with the semiconductor substrate 10. The nitride film 5 is sometimes omitted.

The semiconductor device is sealed with a mold resin 7 that covers the upper surface and an end surface of the semiconductor substrate 10.

As described above, an upper surface in the outer peripheral region 3 of the semiconductor substrate 10 is covered with the field oxide film 4, the nitride film 5, the protective film 6, and the mold resin 7. For example, when only the n⁺ impurity layer 11 is disposed in the surface layer in the outer peripheral region 3, the upper surface in the outer peripheral region 3 is in an electron rich state. In this state, when interlayer cracking occurs between the semiconductor substrate 10 and the field oxide film 4, the nitride film 5, the protective film 6, or the mold resin 7 covering the semiconductor substrate 10 due to expansion/contraction stress, a discharge current flows through the portion to generate an oxide to cause interlayer cracking to further progress.

In contrast, in the present embodiment, the p⁺ impurity layer 12 is disposed in the surface layer of the n⁺ impurity layer 11, and thus an electron rich region is narrow. This suppresses the discharge current when interlayer cracking occurs to suppress generation of the oxide, so that an effect of suppressing progress of interlayer cracking is obtained. As a result, a breakdown voltage failure of the semiconductor device is suppressed.

As for adhesion of the field oxide film 4, the nitride film 5, the protective film 6, and the mold resin 7 to the semiconductor substrate 10, the field oxide film 4 or the nitride film 5 has the highest adhesion, the protective film 6 has the next highest adhesion, and the mold resin 7 has the lowest adhesion herein. Interlayer cracking is thus likely to occur at an interface between the semiconductor substrate 10 and the mold resin 7. The p⁺ impurity layer 12 is thus preferably disposed so that at least a portion of an upper surface thereof is in contact with the mold resin 7.

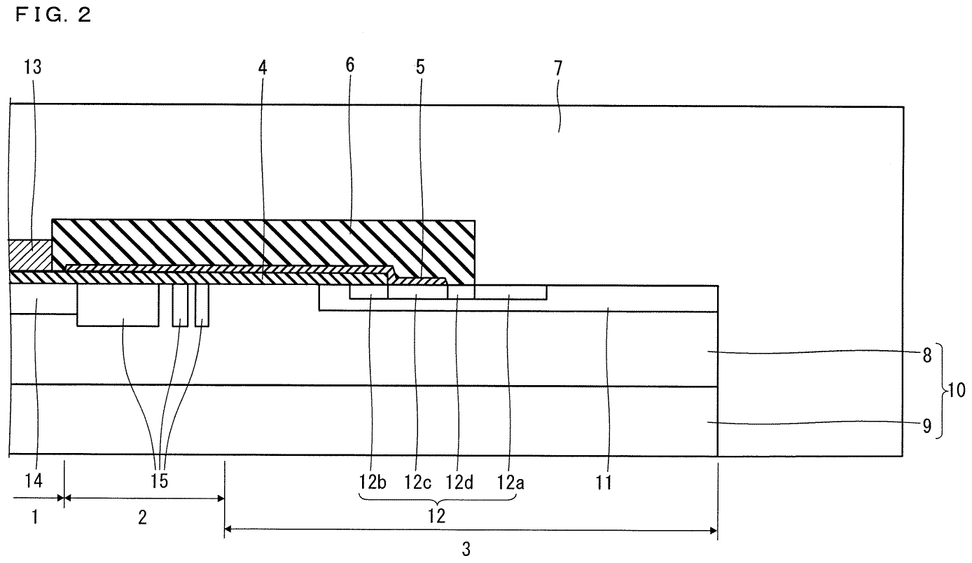

The above-mentioned effect is improved as the p⁺ impurity layer 12 has a higher impurity concentration. While the p⁺ impurity layer 12 has a uniform lateral impurity concentration in the present embodiment, when the p⁺ impurity layer 12 is divided into a first region 12a in which the upper surface is in contact with the mold resin 7, a second region 12b in which the upper surface is in contact with the field oxide film 4, a third region 12c in which the upper surface is in contact with the nitride film 5, and a fourth region 12d in which the upper surface is in contact with the protective film 6 as illustrated in FIG. 2, the p⁺ impurity layer 12 may have a higher impurity concentration in a region in which adhesion to a layer above the region is lower. That is to say, the p⁺ impurity layer 12 may have a higher impurity concentration in the first region 12a than in the second region 12b. The p⁺ impurity layer 12 may have a higher impurity concentration in the first region 12a than in the third region 12c. The p⁺ impurity layer 12 may have a higher impurity concentration in the first region 12a than in the fourth region 12d. The p⁺ impurity layer 12 may have a higher impurity concentration in the fourth region 12d than in the second region 12b. The p⁺ impurity layer 12 may have a higher impurity concentration in the fourth region 12d than in the third region 12c.

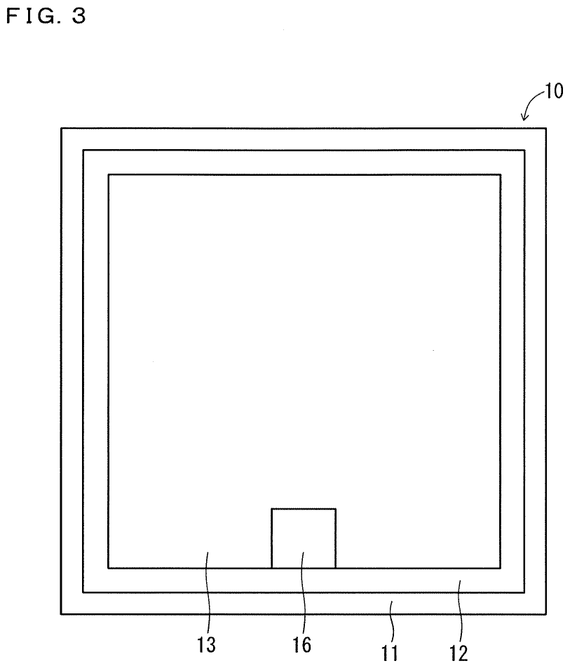

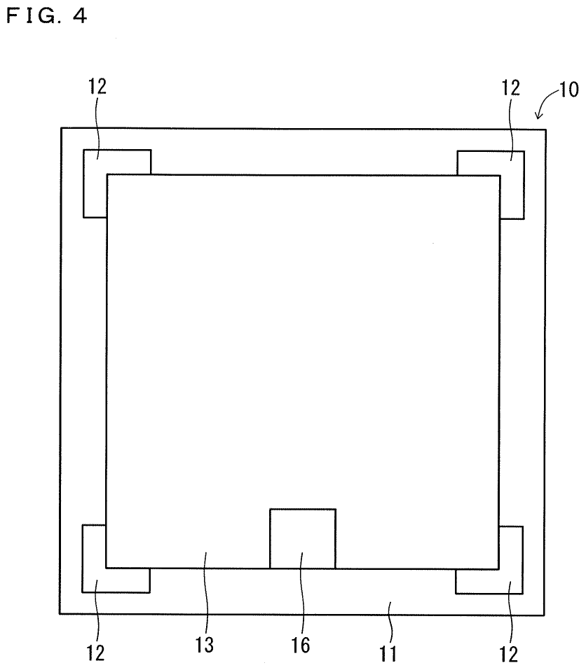

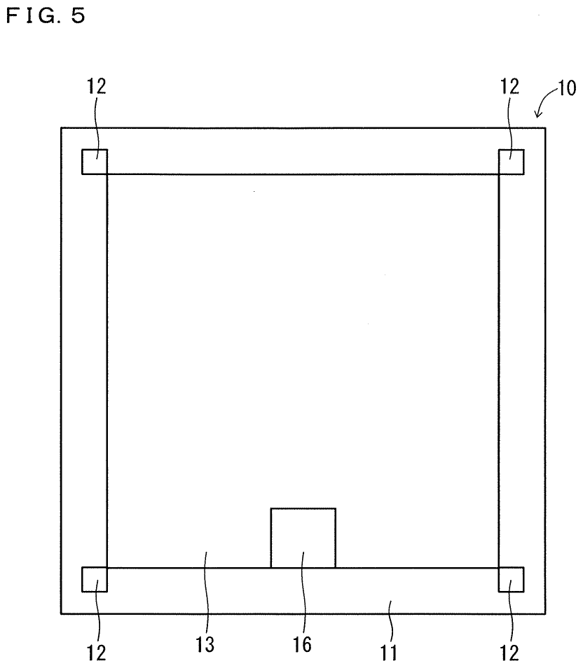

FIG. 3 is a diagram illustrating a planar configuration of the semiconductor device according to Embodiment 1. An element bearing a reference sign “16” in FIG. 3 is a gate pad for inputting a signal into a gate electrode (not illustrated) of the MOSFET. The n⁺ impurity layer 11 as the channel stopper is typically disposed in a ring at an outer periphery of the semiconductor substrate 10. The p⁺ impurity layer 12 is thus preferably disposed in a ring in the surface layer of the n⁺ impurity layer 11 as illustrated in FIG. 3. The p⁺ impurity layer 12, however, may not necessarily be in a ring. For example, when the semiconductor substrate 10 is rectangular in plan view, the expansion/contraction stress concentrates at each corner of the semiconductor substrate 10, so that interlayer cracking is likely to occur at each corner of the semiconductor substrate 10. A certain effect is thus obtained when the p⁺ impurity layer 12 is disposed at least at each corner of the semiconductor substrate 10. For example, the p⁺ impurity layer 12 may be disposed only at each corner of the semiconductor substrate 10 as illustrated in FIG. 4 or 5.

The example in which the semiconductor substrate 10 is made of a material including silicon carbide (SiC) is shown in the present embodiment. The SiC semiconductor device is excellent in operation at a high temperature and is expected to be used in a high temperature environment, so that an effect of preventing breakage of the semiconductor device due to the expansion/contraction stress is particularly effective for the SiC semiconductor device.

### Embodiment 2

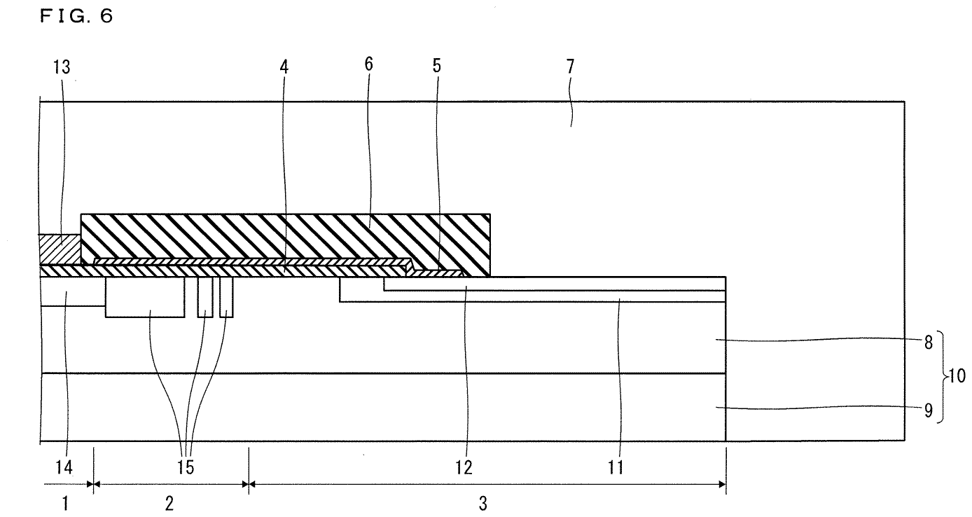

FIG. 6 is a diagram illustrating a configuration of a semiconductor device according to Embodiment 2. Compared with the configuration according to Embodiment 1 (FIG. 1), the configuration of the semiconductor device according to Embodiment 2 is a configuration in which the p⁺ impurity layer 12 extends so that an outer end of the p⁺ impurity layer 12 reaches an outer peripheral end of the n⁺ impurity layer 11 (herein the end of the semiconductor substrate 10). In the present embodiment, the p⁺ impurity layer 12 is disposed at least in a surface layer at the outer peripheral end of the n⁺ impurity layer 11. The other configuration is similar to that in Embodiment 1, so that description thereof is omitted herein.

Interlayer cracking often occurs at the end of the semiconductor substrate 10. The effect of suppressing progress of interlayer cracking is improved by disposing the p⁺ impurity layer 12 at the outer peripheral end of the n⁺ impurity layer 11 close to the end of the semiconductor substrate 10.

### Embodiment 3

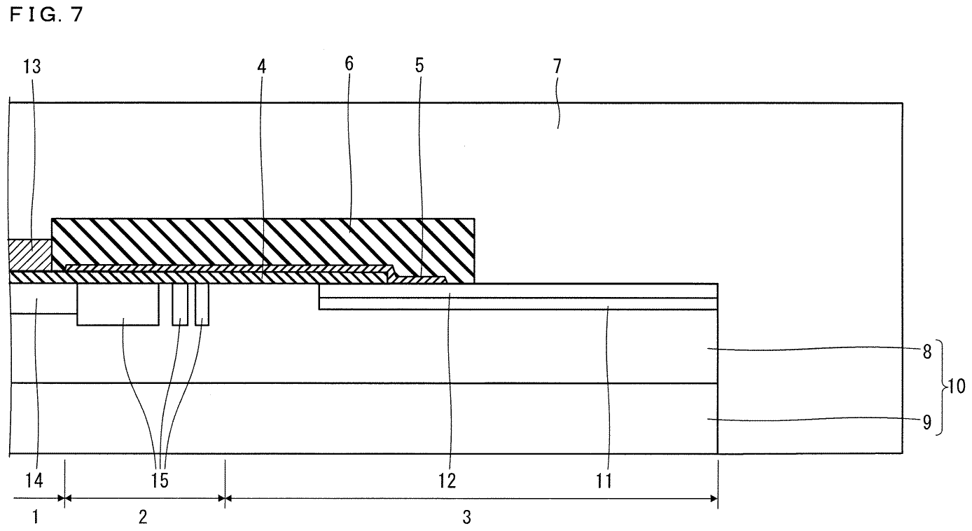

FIG. 7 is a diagram illustrating a configuration of a semiconductor device according to Embodiment 3. Compared with the configuration according to Embodiment 1 (FIG. 1), the configuration of the semiconductor device according to Embodiment 3 is a configuration in which the p⁺ impurity layer 12 is disposed in the entire surface layer of the n⁺ impurity layer 11. The other configuration is similar to that in Embodiment 1, so that description thereof is omitted herein.

In the present embodiment, the p⁺ impurity layer 12 is disposed over an entire upper surface of the n⁺ impurity layer 11, so that a region in which the upper surface is in the electron rich state is not present in the outer peripheral region 3. Generation of the discharge current when interlayer cracking occurs can thus be prevented to prevent generation of the oxide. The effect of suppressing progress of interlayer cracking is further improved compared with that in each of Embodiments 1 and 2.

Embodiments can freely be combined with each other and can be modified or omitted as appropriate.

### Appendices

Various aspects of the present disclosure will collectively be described below as appendices.

### Appendix 1

A semiconductor device comprising:
a semiconductor substrate having an effective region, a breakdown voltage holding region outside the effective region, and an outer peripheral region outside the breakdown voltage holding region, the effective region being a region in which a main current flows, the breakdown voltage holding region being a region in which a p-type breakdown voltage holding structure is disposed;
an n-type impurity layer disposed in at least a portion of a surface layer in the outer peripheral region;
a p-type impurity layer disposed in at least a portion of a surface layer of the n-type impurity layer; and
a mold resin covering an upper surface and an end surface of the semiconductor substrate.

### Appendix 2

The semiconductor device according to Appendix 1, wherein
the p-type impurity layer is disposed at least in a surface layer at an outer peripheral end of the n-type impurity layer.

### Appendix 3

The semiconductor device according to Appendix 1, wherein
the p-type impurity layer is disposed in an entire surface layer of the n-type impurity layer.

### Appendix 4

The semiconductor device according to any one of Appendices 1 to 3, wherein
at least a portion of an upper surface of the p-type impurity layer is in contact with the mold resin.

### Appendix 5

The semiconductor device according to any one of Appendices 1 to 4, wherein
the semiconductor substrate is rectangular in plan view,
the n-type impurity layer is disposed in a ring at an outer periphery of the semiconductor substrate, and
the p-type impurity layer is disposed in a surface layer of the n-type impurity layer at least at each corner of the rectangular semiconductor substrate.

### Appendix 6

The semiconductor device according to any one of Appendices 1 to 4, wherein
the n-type impurity layer is disposed in a ring at an outer periphery of the semiconductor substrate, and
the p-type impurity layer is disposed in a ring in a surface layer of the n-type impurity layer.

### Appendix 7

The semiconductor device according to any one of Appendices 1 to 6, wherein
the semiconductor substrate is made of a material including silicon carbide.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate having an effective region, a breakdown voltage holding region outside the effective region, and an outer peripheral region outside the breakdown voltage holding region, the effective region being a region in which a main current flows, the breakdown voltage holding region being a region in which a p-type breakdown voltage holding structure is disposed;
an n-type impurity layer disposed in at least a portion of a surface layer in the outer peripheral region;
a p-type impurity layer disposed in at least a portion of a surface layer of the n-type impurity layer; and
a mold resin covering an upper surface and an end surface of the semiconductor substrate.

2. The semiconductor device according to claim 1, wherein
the p-type impurity layer is disposed at least in a surface layer at an outer peripheral end of the n-type impurity layer.

3. The semiconductor device according to claim 1, wherein
the p-type impurity layer is disposed in an entire surface layer of the n-type impurity layer.

4. The semiconductor device according to claim 1, wherein
at least a portion of an upper surface of the p-type impurity layer is in contact with the mold resin.

5. The semiconductor device according to claim 1, wherein
the semiconductor substrate is rectangular in plan view,
the n-type impurity layer is disposed in a ring at an outer periphery of the semiconductor substrate, and
the p-type impurity layer is disposed in a surface layer of the n-type impurity layer at least at each corner of the rectangular semiconductor substrate.

6. The semiconductor device according to claim 1, wherein
the n-type impurity layer is disposed in a ring at an outer periphery of the semiconductor substrate, and
the p-type impurity layer is disposed in a ring in a surface layer of the n-type impurity layer.

7. The semiconductor device according to claim 1, wherein
the semiconductor substrate is made of a material including silicon carbide.
